(19) United States
(12) Patent Application Publication
(10) Pub. No.: US 2007/0087547 A1
(43) Pub. Date: Apr. 19, 2007

(54) Wafer structure with electroless plating metal connecting layer and method for fabricating the same

(76) Inventors: Shang Wei Chen, Hsin-chu (TW); Zhao Chong Zeng, Hsin-chu (TW); Chung Cheng Lien, Hsin-chu (TW); Shih Ping Hsu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/509,876

(22) Filed: Aug. 24, 2006

(30) Foreign Application Priority Data
Oct. 13, 2005 (TW) 094135636

(51) Int. Cl. H01L 21/44; H01L 23/48; H01L 23/52; H01L 29/40

(52) U.S. Cl. 438/613; 257/737

(57) ABSTRACT

A wafer structure with an electroless plating metal connecting layer and a method for fabricating the same are proposed. A wafer has an active surface and an inactive surface opposite to the active surface. The active surface has a plurality of electrical connecting pads formed thereon. An insulating protective layer is formed on the active surface of the wafer and a plurality of openings are formed in the insulating protective layer to correspond to the electrical connecting pads, so that the electrical connecting pads are exposed. A plurality of electroless plating metal connecting layers are formed on the electrical connecting pads that are exposed through the openings, by electroless plating. Therefore, the electrical connecting process of the wafer is simplified and easily implemented. As a result, the production cost is reduced, the yield is raised, and mass production of high quality is ensured simultaneously.

### CROSS-REFERENCE TO RELATED APPLICATIONS

This application claims benefit under 35 USC 119 of Taiwan Application No. 094135636, filed on Oct. 13, 2005.

### FIELD OF THE INVENTION

The present invention is related to wafer structures and methods for fabricating the same, and more particularly, to a wafer structure with electroless plating metal connecting layer and a method for fabricating the same.

### BACKGROUND OF THE INVENTION

Flip chip semiconductor packaging technique is an advanced technique for packaging semiconductor; it differs from the previously known non-flip chip packaging technique in that the active surface of the semiconductor chip disposed on substrate by this way faces downward, and the semiconductor chip is soldered and electrically connected to the substrate by a plurality of bumps. In a flip chip package structure, bonding wires are not required to electrically connect the semiconductor chip to the substrate, which saves a lot of space and hence effectively shortens the distance of electrical signal transmitting, thereby elevating the electrical quality of the overall package structure and making volume more miniaturized.

Please refer to FIG. 1, before bump 13 is soldered onto wafer 10, it is necessary to form an UBM (Under Bump Metallurgy) structure layer 12 on top of electrical connecting pad 100 of wafer 10 first, UBM structure layer 12 is composed of an adhesive layer 12a formed on electrical connecting pad 100 of the wafer; a barrier layer 12b whose purpose is to prevent diffusion, and a wettable layer 12c that is used to connect bump 13. By relying on the functions of UBM structure layer 12, such as providing connection to the bump, diffusion barrier, and adequate adhesiveness, solder material can be formed on electrical connecting pad 100 of wafer 10, and spread evenly on each and every UBM structure layer; the added solder then undergoes the reflow procedure to form bump 13 as required.

However, the completion of electrical connection in the wafer described above needs additional UBM structure layer, and the UBM structure layer is generally made of Titanium-Copper-Nickel metal layers, which results in complicated production process and higher cost. Additionally, the increasing demand for fine bump pitch makes the production of bump even more difficult, which gives rise to problems like higher production cost and lower yield.

Therefore, the issue that requires immediate attention from the industry is about finding solutions for problems like how to simplify the electrical connection process of wafer, how to lower production cost, how to raise yield, and how to ensure mass production of high quality all at the same time.

### SUMMARY OF THE INVENTION

With the drawbacks of the prior arts in mind, the primary objective of the present invention is to provide a wafer structure with an electroless plating metal connecting layer and a method for fabricating the same, wherein the electroless plating metal connecting layer is formed on top of the electrical connecting pad of wafer by electroless plating, so that the electroless plating metal connecting layer is firmly connected to the electrical connecting pad.

Another objective of the present invention is to provide a wafer structure with an electroless plating metal connecting layer and a method for fabricating the same, which can simplify the process of metal connection in wafer and thereby facilitating the implementation of the process.

Another objective of the present invention is to provide a wafer structure with an electroless plating metal connecting layer and a method for fabricating the same, which do not need to produce expensive structures like UBM structure and bump additionally.

A further objective of the present invention is to provide a wafer structure with an electroless plating metal connecting layer and a method for fabricating the same, which can lower production cost, increase yield, and ensure mass production of high quality.

To accomplish the above and other objectives, the present invention provides a wafer structure with an electroless plating metal connecting layer and a method for fabricating the same, which is composed of: a wafer having an active surface and an inactive surface opposite to the active surface, wherein the active surface has a plurality of electrical connecting pads formed thereon; an insulating protective layer formed on the active surface of the wafer, wherein the insulating protective layer has a plurality of openings formed in positions corresponding to the electrical connecting pads to expose the electrical connecting pads; and a plurality of electroless plating metal connecting layers formed on the electrical connecting pads that are exposed through the openings by electroless plating.

In the wafer structure with electroless plating metal connecting layer described above, the electrical connecting pads are copper electrode pads; the insulating protective layer is an organic insulating protective layer, which can either be Benzo-Cyclo-Butene, polyimide, or other organic materials; the preferable material for the electroless plating metal connecting layer is copper.

In order to make a wafer structure with the electroless plating metal connecting layer mentioned above, the present invention provides a method for producing a wafer structure with the electroless plating metal connecting layer, the method includes the following steps: providing a wafer having an active surface and an inactive surface opposite to the active surface, wherein the active surface has a plurality of electrical connecting pads formed thereon; forming an insulating protective layer on the active surface of the wafer, wherein the insulating protective layer has a plurality of openings formed in positions corresponding to the electrical connecting pads to expose the electrical connecting pads; and forming an electroless plating metal connecting layer on a surface of each of the electrical connecting pads by electroless plating.

In the wafer structure with the electroless plating metal connecting layer above, the substrate can be further comprised of a dicing process, so that a single chip with electroless plating metal connecting layer can be produced.

According to the present invention, the wafer structure with electroless plating metal connecting layer and the method for fabricating the same propose that the electroless plating metal connecting layer is directly formed on top of the electrical connecting pad of wafer by electroless plating, and thus the electrical connecting structure of the wafer can be formed without having to produce expensive structures like UBM structure and bump. In addition to that, the material of electroless plating metal connecting layer can either be copper, silver, gold, or a combination of the previous and other metals (preferable copper), and hence the connection between the electrical connecting pad and the electroless plating metal connecting layer can be improved. In summary, according to the present invention, the wafer structure with electroless plating metal connecting layer and the method for fabricating the same can simplify the electrical connecting process of the wafer to facilitate its implementation, and effectively reduce production cost, elevate yield and ensure mass production of high quality.

### BRIEF DESCRIPTION OF THE DRAWINGS

The present invention can be more fully comprehended by reading the detailed description of the embodiments listed below, with reference made to the accompanying drawings, wherein:

FIG. 1 is a cross-sectional view showing the wafer with UBM structure layer and bump in accordance with the prior art; and

FIG. 2A to 2D are schematic cross-sectional views showing the wafer structure with electroless plating metal connecting layer and the method for fabricating the same, according to the present invention.

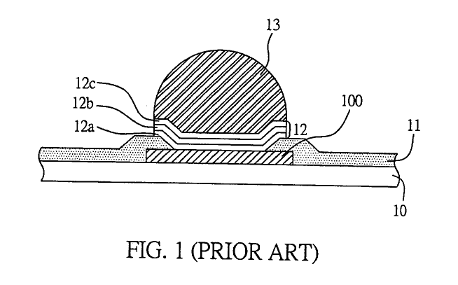

### DETAILED DESCRIPTION OF THE INVENTION

The present invention relates generally to wafer structures and methods for fabricating the same, and more particularly, to a wafer structure with electroless plating metal connecting layer and a method for fabricating the same. The following description is presented to enable one of ordinary skill in the art to make and use the invention and is provided in the context of a patent application and its requirements. Various modifications to the embodiments and the generic principles and features described herein will be readily apparent to those skilled in the art. Thus, the present invention is not intended to be limited to the embodiments shown, but is to be accorded the widest scope consistent with the principles and features described herein.

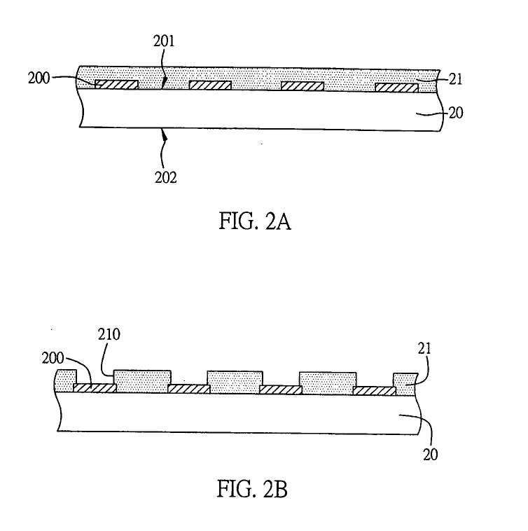

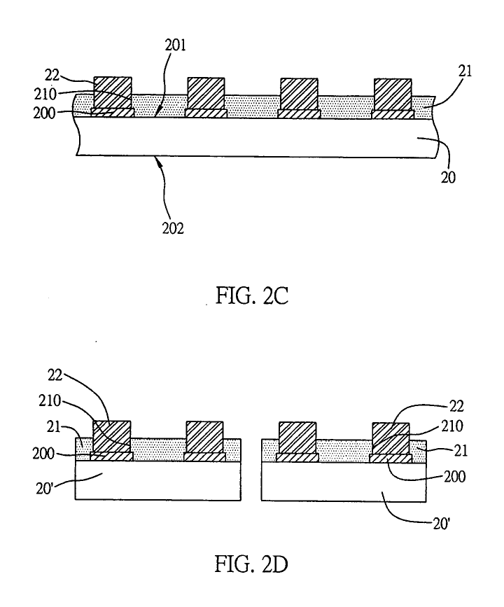

FIGS. 2A to 2E are used to elucidate the wafer structure with electroless plating metal connecting layer and the method for fabricating the same, according to the present invention.

First of all, as shown in FIG. 2A, a wafer 20 is supplied; it has an active surface 201 and an inactive surface 202 opposite to active surface 201, and a plurality of electrical connecting pads 200 are formed on active surface 201; an insulating protective layer 21 is also formed on active surface 201 of wafer 20 that has a plurality of electrical connecting pads 200. The electrical connecting pads 200 are electrode pads made of metal material, the preferable material for the electrode pads is copper; the insulating protective layer 21 is an organic insulating protective layer, it is designed to protect the surface of the wafer and prevent the copper electrode pads from oxidation; the preferable material for the organic insulating protective layer can be selected from either Benzo-Cyclo-Butene, polyimide, or other organic materials.

As shown in FIG. 2B, a plurality of openings 210 are formed in the positions of insulating protective layer 21 that are opposited to electrical connecting pads 200, so that electrical connecting pads 200 are exposed. Because the insulating protective layer 21 is an organic insulating protective layer, the surface of the wafer with organic insulating protective layer can be processed to make openings and remove oxidized copper layer by the method of plasma etching, reactive ion etching, or laser.

As shown in FIG. 2C, an electroless plating metal connecting layer 22 is formed on the surface of insulating protective layer 21 by electroless plating deposition, so that the electroless plating metal connecting layer 22 is electrically connected to the electrical connecting pads 200 of wafer 20. In this embodiment, the electroless plating metal connecting layer 22 is deposited on top of electrical connecting pad 200 by electroless plating a layer of copper on electrical connecting pad 200. Since the electrical connecting pad 200 is also made of copper, the electroless plating metal connecting layer 22 can be directly formed on and firmly connected to the electrical connecting pad 200. Moreover, because there is no metal seed layer (such as Palladium) on the surface of insulating protective layer 21, the metal copper will not attach to the surface of the insulating protective layer.

In addition, please refer to FIG. 2D, the method of the present invention can further comprise a dicing process that is carried out on the wafer with electroless plating metal connecting layer, so that a single chip 20′ with the electroless plating metal connecting layer 22 can be produced.

By following the method of the present invention described above, a wafer structure with electroless plating metal connecting layer can be produced. As shown in FIG. 2C, the structure is composed of: a wafer 20 that has an active surface 201 and an inactive surface 202 opposite to active surface 201, and a plurality of electrical connecting pads 200 that are formed on active surface 201; an insulating protective layer 21 formed on active surface 201 of the wafer that has a plurality of electrical connecting pads 200, and a plurality of openings 210 are formed in the positions of insulating protective layer 21 that are opposite to electrical connecting pads 200, so that electrical connecting pads 200 are exposed; a plurality of electroless plating metal connecting layer 22 are formed by electroless plating on electrical connecting pads 200 that are exposed through openings 210.

In the wafer structure with electroless plating metal connecting layer above, the electrical connecting pads 200 are electrode pads made of copper; the insulating protective layer 21 is an organic insulating protective layer and can be selected from either Benzo-Cyclo-Butene, polyimide, or other organic materials; it is designed to protect the surface of the wafer and prevent the copper electrode pads from oxidation. The surface of the wafer with organic insulating protective layer can be processed to make openings by the method of plasma etching, reactive ion etching, or laser. The electroless plating metal connecting layer 22 can be made of either copper, silver, gold, or a combination of the previous and other metals (preferable copper); it is made of the same metal material as electrical connecting pad 200, and hence the connection between electroless plating metal connecting layer 22 and electrical connecting pad 200 can be improved. As a result, once the wafer is diced into individual chips, the electroless plating metal connecting layer can be used for external electrical connection or as the interface for re-wiring conductive circuits.

In summary, in the wafer structure with electroless plating metal connecting layer and the method for fabricating the same according to the present invention, the electroless plating metal connecting layer is directly formed on top of the electrical connecting pad of wafer by electroless plating, which is convenient and efficient. Thus it no longer needs to produce expensive structures like the UBM structure and bump to form the electrical connecting structure of wafer. Additionally, the electroless plating metal connecting layer is made of the same metal material as the electrical connecting pad, so the connection between the electrical connecting pad and the electroless plating metal connecting layer can be reinforced. Therefore, the wafer structure with electroless plating metal connecting layer and the method for fabricating the same according to the present invention can simplify the electrical connecting process of the wafer, thereby facilitating its implementation, and effectively reducing production cost, elevating yield and ensuring mass production of high quality.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for fabricating a wafer structure with an electroless plating metal connecting layer, comprising:
providing a wafer having an active surface and an inactive surface opposite to the active surface, wherein the active surface has a plurality of electrical connecting pads formed thereon;
forming an insulating protective layer on the active surface of the wafer, wherein the insulating protective layer has a plurality of openings formed in positions corresponding to the electrical connecting pads to expose the electrical connecting pads; and
forming an electroless plating metal connecting layer on a surface of each of the electrical connecting pads by electroless plating.

2. The method of claim 1, wherein the electrical connecting pads are electrode pads made of copper.

3. The method of claim 1, wherein the insulating protective layer is an organic insulating protective layer.

4. The method of claim 1, wherein the electroless plating metal connecting layer can be made of either copper, silver, gold, or a combination of the previous and other metals.

5. The method of claim 1, further comprising a dicing process to produce a single chip with the electroless plating metal connecting layer.

6. A wafer structure with an electroless plating metal connecting layer, comprising:
a wafer having an active surface and an inactive surface opposite to the active surface, wherein the active surface has a plurality of electrical connecting pads formed thereon;
an insulating protective layer formed on the active surface of the wafer, wherein the insulating protective layer has a plurality of openings formed in positions corresponding to the electrical connecting pads to expose the electrical connecting pads ; and
a plurality of electroless plating metal connecting layers formed on the electrical connecting pads exposed through the openings by electroless plating.

7. The structure of claim 6, wherein the electrical connecting pads are electrode pads made of copper.

8. The structure of claim 6, wherein the insulating protective layer is an organic insulating protective layer.

9. The structure of claim 6, wherein the electroless plating metal connecting layer can be made of either copper, silver, gold, or a combination of the previous and other metals.
